(19) United States
(12) Patent Application Publication
(10) Pub. No.: US 2020/0075217 A1
(43) Pub. Date: Mar. 5, 2020

(54) CERAMIC MULTILAYER BODY

(71) Applicant: Murata Manufacturing Co., Ltd., Nagaokakyo-shi (JP)

(72) Inventors: Takayuki OKADA, Nagaokakyo-shi (JP); Daigo MATSUBARA, Nagaokakyo-shi (JP)

(21) Appl. No.: 16/679,415

(22) Filed: Nov. 11, 2019

Related U.S. Application Data
(63) Continuation of application No. PCT/JP2018/042776, filed on Nov. 20, 2018.

(30) Foreign Application Priority Data
Dec. 26, 2017 (JP) 2017-249177

(51) Int. Cl. H01F 27/24; H01F 27/33; H01F 27/32; H01F 41/12; H01L 41/09; H01L 41/053

(52) U.S. Cl. CPC H01F 27/24; H01F 27/33; H01F 27/324; H01F 41/041; H01L 41/09; H01L 41/053; H01F 41/125

(57) ABSTRACT

A ceramic multilayer body includes an outer layer including a first ceramic base material, a hollow portion provided in an inner side of the outer layer, an intermediate layer including a second ceramic base material and provided inside the hollow portion, and a pair of coupling portions each coupling one of both principal surfaces of the intermediate layer to the outer layer, wherein a void is provided by the hollow portion between the outer layer and the intermediate layer except for regions occupied by the coupling portions, and wherein, when observed through the ceramic multilayer body in the lamination direction, the pair of coupling portions at least partially overlap with each other, and areas of the pair of coupling portions are each smaller than an area of the intermediate layer. The first ceramic base material and the second ceramic base material have different material compositions from each other.

### CROSS REFERENCE TO RELATED APPLICATIONS

This application claims the benefit of priority to Japanese Patent Application No. 2017-249177 filed on Dec. 26, 2017 and is a Continuation Application of PCT Application No. PCT/JP2018/042776 filed on Nov. 20, 2018. The entire contents of each application are hereby incorporated herein by reference.

### BACKGROUND OF THE INVENTION

### 1. Field of the Invention

The present invention relates to a ceramic multilayer body, and more particularly to a ceramic multilayer body including a layer of a first ceramic base material and a layer of a second ceramic base material that have different material compositions from each other.

### 2. Description of the Related Art

In a ceramic multilayer body such as a ceramic multilayer substrate, multiple layers of ceramic base materials having different material compositions from each other are laminated in some cases, aiming to achieve higher functionality, for example. Japanese Unexamined Patent Application Publication No. 2012-138496 discloses a ceramic multilayer body in which the multiple layers of the ceramic base materials are laminated. FIG. 16 illustrates a ceramic multilayer body (coil built-in substrate) 1500 disclosed in Japanese Unexamined Patent Application Publication No. 2012-138496.

The ceramic multilayer body 1500 includes a nonmagnetic layer 101, a magnetic layer 102, and a ferromagnetic layer (magnetic layer having a high magnetic permeability) 103, those layers being laminated and having different material compositions from each other. A wiring conductor pattern (in-plane wiring conductor) 104, a connection conductor (interlayer connection conductor) 105, and a coil conductor pattern (coil conductor) 106 are provided inside the ceramic multilayer body 1500. An electronic component 107 is mounted to an upper principal surface of the ceramic multilayer body 1500.

In the ceramic multilayer body 1500, because the nonmagnetic layer 101, the magnetic layer 102, and the ferromagnetic layer 103, which are different from each other not only in material composition, but also usually in thermal shrinkage rate, are laminated, there is a possibility that cracks or peeling-off may occur between the layers during firing or during cooling after the firing.

In addition, the nonmagnetic layer 101, the magnetic layer 102, and the ferromagnetic layer 103 are usually further different in sintering temperature from each other. Therefore, it may happen in some cases that, when trying to avoid excessive sintering of any one of the layers, sintering of the other one or more layers become incomplete. Moreover, because the nonmagnetic layer 101, the magnetic layer 102, and the ferromagnetic layer 103 are exposed at an end surface 108 of the ceramic multilayer body 1500, there is a possibility that, if the sintering of any one layer is incomplete, cracks or peeling-off may occur starting from an interface between the properly sintered layer and the incompletely sintered layer, those layers being exposed at the end surface 108.

### SUMMARY OF THE INVENTION

Preferred embodiments of the present invention provide ceramic multilayer bodies that each include layers laminated in a predetermined lamination direction and including a layer of a first ceramic base material and a layer of a second ceramic base material having different material compositions from each other, the ceramic multilayer body including an outer layer including the first ceramic base material, a hollow portion provided in an inner side of the outer layer and being hollow, an intermediate layer including the second ceramic base material and provided inside the hollow portion, and a pair of coupling portions each coupling one of both principal surfaces of the intermediate layer to the outer layer, wherein a void is provided by the hollow portion between the outer layer and the intermediate layer except for regions occupied by the coupling portions, and wherein, when observed through the ceramic multilayer body in the lamination direction, the pair of coupling portions at least partially overlap with each other, and areas of the pair of coupling portions are each smaller than an area of the intermediate layer.

Here, the wording “having different material compositions from each other” implies not only the case in which elements included in the materials are different, but also the case in which elements included in the materials are the same and mixing ratios are different.

The coupling portion may include, for example, the second ceramic base material. Alternatively, the coupling portion may include the first ceramic base material.

Preferably, for example, at least a portion of the coupling portion includes metal. In this case, since metals are mostly softer than ceramics, the coupling portion is able to significantly reduce the difference in thermal shrinkage rate between the outer layer and the intermediate layer with the aid of the included metal, and can satisfactorily couple the outer layer and the intermediate layer. Furthermore, the metal can also be utilized as a connection conductor.

Preferably, the ceramic multilayer body further includes a coil conductor pattern provided therein, the coil conductor pattern is wound about a winding axis extending in the lamination direction, and the coil conductor pattern defines a coil. In this case, the ceramic multilayer body including the coil can be provided.

Preferably, the ceramic multilayer body further includes wiring conductor patterns provided therein, the wiring conductor patterns are provided respectively in portions of the outer layer in opposite sides sandwiching the intermediate layer therebetween, and the wiring conductor patterns are electrically connected to each other by a connection conductor provided in the intermediate layer. In this case, the ceramic multilayer body having significantly increased functionality can be provided.

Preferably, the second ceramic base material is a magnetic substance. A magnetic bead inductor (ferrite bead inductor when the magnetic substance is ferrite) can be defined by provided the connection conductor to penetrate through the intermediate layer that includes the magnetic substance used as the second ceramic base material. Hence a noise component included in a signal flowing in the connection conductor is significantly reduced or prevented from passing through the connection conductor.

Preferably, the second ceramic base material is a piezoelectric substance. In this case, a piezoelectric vibration component can be defined inside the ceramic multilayer body.

Preferably, when observed through the ceramic multilayer body in the lamination direction, the coupling portion has a circular or elliptic shape. The coupling portion having the circular or elliptic shape when observed through the ceramic multilayer body in the lamination direction is able to further significantly reduce the difference in thermal shrinkage rate between the outer layer and the intermediate layer and can more satisfactorily couple the outer layer and the intermediate layer than a coupling portion having corners, for example, a rectangular or substantially rectangular coupling portion.

Preferably, for example, when observed through the ceramic multilayer body in the lamination direction, the coupling portion is provided at a position overlapping with the center of gravity of the intermediate layer. In this case, the intermediate layer is stably supported inside the hollow portion that is provided in the inner side of the outer layer.

According to the ceramic multilayer body of the preferred embodiments of the present invention, since the void is provided between the outer layer and the intermediate layer except for the regions occupied by the coupling portions, cracks or peeling-off is hard to occur between the outer layer and the intermediate layer during firing or during cooling after the firing even when the material composition of the first ceramic base material provided the outer layer is different from that of the second ceramic base material provided the intermediate layer.

Furthermore, according to the ceramic multilayer body of the preferred embodiments of the present invention, even in the case of either one of the outer layer and the intermediate layer being sintered incompletely, since only the outer layer is exposed to an end surface of the ceramic multilayer body and the interface between the outer layer and the intermediate layer is not present at the end surface, cracks or peeling-off starting from that interface do not occur.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A and 1B are each a sectional view of a ceramic multilayer body 100 according to a first preferred embodiment of the present invention; specifically, FIG. 1B shows a section X-X denoted by a one-dot-chain line in FIG. 1A.

FIGS. 2A to 2C are sectional views showing steps performed in an example of a method of manufacturing the ceramic multilayer body 100.

FIGS. 3D to 3F are sectional views showing steps performed, following the step of FIG. 2C, in the example of the method of manufacturing the ceramic multilayer body 100.

FIGS. 4G to 4I are sectional views shows steps performed, following the step of FIG. 3F, in the example of the method of manufacturing the ceramic multilayer body 100.

FIG. 5 is a sectional view of a ceramic multilayer body 200 according to a second preferred embodiment of the present invention.

FIG. 6 is a sectional view of a ceramic multilayer body 300 according to a third preferred embodiment of the present invention.

FIG. 7 is a sectional view of a ceramic multilayer body 400 according to a fourth preferred embodiment of the present invention.

FIG. 8 is a sectional view of a ceramic multilayer body 500 according to a fifth preferred embodiment of the present invention.

FIG. 9 is a sectional view of a ceramic multilayer body 600 according to a sixth preferred embodiment of the present invention.

FIG. 10 is a sectional view of a ceramic multilayer body 700 according to a seventh preferred embodiment of the present invention.

FIG. 11 is a sectional view of a ceramic multilayer body 800 according to an eighth preferred embodiment of the present invention.

FIG. 12 is a sectional view of a ceramic multilayer body 900 according to a ninth preferred embodiment of the present invention.

FIG. 13 is a sectional view of a ceramic multilayer body 1000 according to a tenth preferred embodiment of the present invention.

FIG. 14 is a sectional view of a ceramic multilayer body 1100 according to an eleventh preferred embodiment of the present invention.

FIG. 15 is a sectional view of a ceramic multilayer body 1200 according to a twelfth preferred embodiment of the present invention.

FIG. 16 is a sectional view of the ceramic multilayer body 1500 disclosed in Japanese Unexamined Patent Application

### DETAILED DESCRIPTION OF THE PREFERRED EMBODIMENTS

Preferred embodiments of the present invention will be described below with reference to the drawings.

The following preferred embodiments merely show practical examples of the present invention, and the present invention is not limited to the matters disclosed in the following preferred embodiments. The matters disclosed in the different preferred embodiments may be implemented in combination with one another, and modifications implemented in combined configurations also fall within the scope of the present invention. The drawings are shown to merely assist understanding of the description and are schematically shown in some cases. Sizes of shown elements and size ratios between the elements are not always in agreement with those stated in the description. In other cases, the elements disclosed in the description may be omitted in the drawings or shown in reduced number.

### First Preferred Embodiment

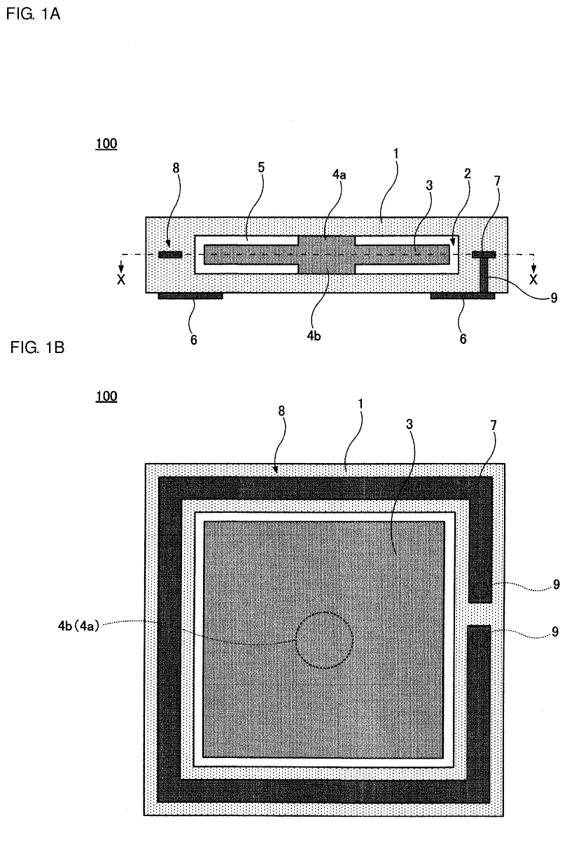

FIGS. 1A and 1B show a ceramic multilayer body 100 according to a first preferred embodiment of the present invention. More specifically, FIGS. 1A and 1B are each a sectional view of the ceramic multilayer body 100; specifically, FIG. 1B shows a section X-X denoted by a one-dot-chain line in FIG. 1A.

The ceramic multilayer body 100 includes an outer layer 1 including a nonmagnetic substance that is used as a first ceramic base material. The nonmagnetic substance may have any suitable material composition. For example, nonmagnetic ceramic, such as alumina or nonmagnetic ferrite, can be used as the nonmagnetic substance. Because the nonmagnetic substance is insulating, it can also be called an insulator. The outer layer 1 is provided by laminating a plurality of green sheets each including ceramic powder of the nonmagnetic substance used as the first ceramic base material, and by forming the laminated green sheets into an integral body through press-binding and firing. Interfaces between the layers remain in some cases and do not remain in other cases after the firing.

In the first preferred embodiment, the outer layer 1 preferably has a rectangular parallelepiped or substantially rectangular parallelepiped shape. However, the outer layer 1 may have any suitable shape.

A hollow portion 2 is provided in the inner side of the outer layer 1. In the first preferred embodiment, the hollow portion 2 is preferably a rectangular parallelepiped or substantially rectangular parallelepiped cavity. However, the hollow portion 2 may have any suitable shape.

An intermediate layer 3 including a magnetic substance used as a second ceramic base material is provided inside the hollow portion 2. The magnetic substance may have any suitable material composition. For example, magnetic ceramic can be used as the magnetic substance. More specifically, ferrite including iron oxide as a main ingredient and at least one among zin, nickel and copper can be used, by way of example. Because the magnetic substance is insulating, it can also be called an insulator.

In the first preferred embodiment, the intermediate layer 3 preferably has a rectangular parallelepiped or substantially rectangular parallelepiped shape. However, the intermediate layer 3 may have any suitable shape.

Upper and lower principal surfaces of the intermediate layer 3 are coupled to the outer layer 1 by coupling portions 4a and 4b. In the first preferred embodiment, the coupling portions 4a and 4b preferably include the magnetic substance used as the second ceramic base material, i.e., the same or similar material as that of the intermediate layer 3. However, the coupling portions 4a and 4b may have any suitable material composition.

In the first preferred embodiment, each of the coupling portions 4a and 4b has a circular or substantially circular columnar shape. However, each of the coupling portions 4a and 4b may have any suitable shape such as an elliptic or substantially elliptical columnar shape, for example. As an alternative, the shape of the coupling portions 4a and 4b may be rectangular parallelepiped or substantially rectangular parallelepiped.

A void 5 is provided between the outer layer 1 and the intermediate layer 3 except for regions occupied by the coupling portions 4a and 4b.

When observed through the ceramic multilayer body 100 in a lamination direction of the outer layer 1 and the intermediate layer 3, the coupling portion 4a and the coupling portion 4b overlap with each other. Furthermore, an area of each of the coupling portions 4a and 4b is smaller than that of the intermediate layer 3. In addition, the coupling portions 4a and 4b each match with the center of gravity of the intermediate layer 3.

A plurality of outer electrodes 6 are provided at a bottom surface of the ceramic multilayer body 100.

A coil conductor pattern 7 is annularly provided between the layers defining the outer layer 1 outside the hollow portion 2. In other words, when observed through the ceramic multilayer body 100 in the lamination direction, the coil conductor pattern 7 is provided outside both the intermediate layer 3 and the hollow portion 2. Furthermore, the coil conductor pattern 7 is at the same or substantially the same height level in the lamination direction as a level at which the intermediate layer 3 and the hollow portion 2 are provided. The coil conductor pattern 7 has a winding axis extending in the lamination direction of the outer layer 1 and the intermediate layer 3. In the first preferred embodiment, a coil 8 is preferably defined by one turn of winding formed by the coil conductor pattern 7. However, the number of turns of the coil 8 can be set to any suitable value, and multiple turns of winding may be defined by connecting the coil conductor patterns 7, which are provided between different adjacent twos of the layers, through connection conductors (via conductors).

One end of the coil 8 is connected to one of the outer electrodes 6 by a connection conductor 9. Though not shown, the other end of the coil 8 is connected to other outer electrode 6 by another connection conductor 9.

The outer electrodes 6, the coil conductor pattern 7, and the connection conductor 9 can each be made of any suitable material. For example, a material including silver as a main ingredient may be used.

The ceramic multilayer body 100 according to the first preferred embodiment has the following features.

In the ceramic multilayer body 100, the intermediate layer 3 is made of the magnetic substance used as the second ceramic base material in a region where the winding axis of the coil 8 defined inside the ceramic multilayer body 100 is positioned, and the intermediate layer 3 defines and functions as a magnetic core. In the ceramic multilayer body 100, therefore, the coil 8 has a large inductance value.

In the ceramic multilayer body 100, since the void 5 is provided between the outer layer 1 and the intermediate layer 3 except for the regions occupied by the coupling portions 4a and 4b, cracks or peeling-off are hard to occur between the outer layer 1 and the intermediate layer 3 in a firing step or a cooling step after the firing in a manufacturing process even when the material composition of the first ceramic base material of the outer layer 1 is different from that of the second ceramic base material of the intermediate layer 3 and thermal shrinkage rates of the outer layer 1 and the intermediate layer 3 are different from each other.

More specifically, if the outer layer 1 and the intermediate layer 3 are contacted with each other over a larger area, cracks or peeling-off tend to more easily occur between the outer layer 1 and the intermediate layer 3 in the firing step or the cooling step after the firing. In the ceramic multilayer body 100, however, since the outer layer 1 and the intermediate layer 3 are coupled to each other by only the coupling portions 4a and 4b, cracks or peeling-off are harder to occur between the outer layer 1 and the intermediate layer 3.

In the ceramic multilayer body 100, even in the case of either one of the outer layer 1 and the intermediate layer 3 being sintered incompletely, since only the outer layer 1 is exposed to an end surface of the ceramic multilayer body 100 and the interface between the outer layer 1 and the intermediate layer 3 is not present at the end surface, cracks or peeling-off starting from that interface do not occur.

In the ceramic multilayer body 100, since the coupling portion 4a and the coupling portion 4b overlap with each other when observed through the ceramic multilayer body 100 in the lamination direction, the intermediate layer 3 is satisfactorily supported inside the hollow portion 2. The coupling portion 4a and the coupling portion 4b are not always required to completely overlap, but preferably at least partially overlap, for example.

Furthermore, since the area of each of the coupling portions 4a and 4b is smaller than that of the intermediate layer 3 when observed through the ceramic multilayer body 100 in the lamination direction, the outer layer 1 and the intermediate layer are coupled through the comparatively small area, cracks or peeling-off are hard to occur between the outer layer 1 and the intermediate layer 3 in a manufacturing process, i.e., in the firing step or the cooling step after the firing.

Moreover, in the ceramic multilayer body 100, since the coupling portions 4a and 4b each match with the center of gravity of the intermediate layer 3 when observed through the ceramic multilayer body 100 in the lamination direction, the intermediate layer 3 is stably supported inside the hollow portion 2 that is defined by the outer layer 1.

The ceramic multilayer body 100 can be manufactured by the following non-limiting exemplary method, for example.

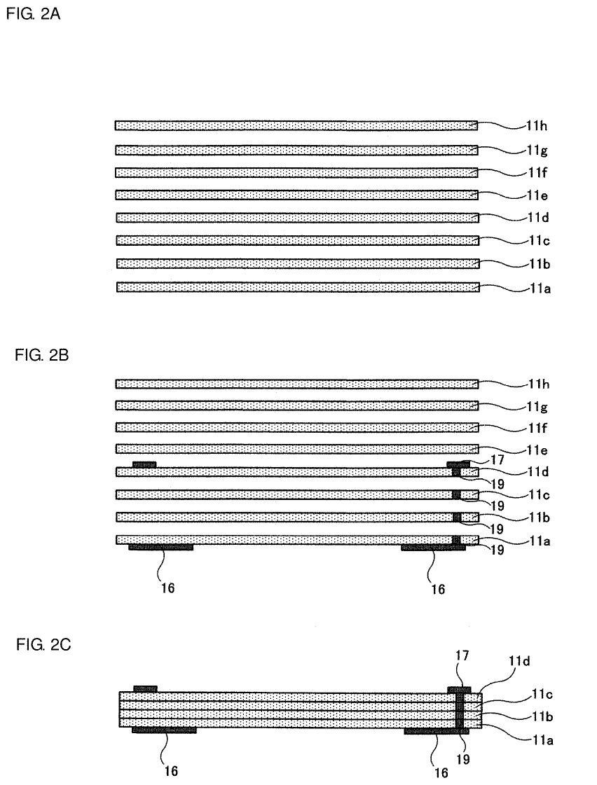

First, as shown in FIG. 2A, ceramic green sheets 11a to 11h to form the outer layer 1 are fabricated.

The green sheets 11a to 11h are each fabricated by adding a binder and a solvent to ceramic powder of the nonmagnetic substance used as the first ceramic base material, thus preparing slurry, and by shaping the prepared slurry into the form of a film by the doctor blade method, for example.

Then, as shown in FIG. 2B, through-holes to form the connection conductors 9 are formed in the green sheets 11a to 11d by irradiation of a laser beam, for example. Subsequently, a conductive paste 19 to form the connection conductors 9 is filled into the formed through-holes. Moreover, a conductive paste 16 to form the outer electrodes 6 is coated in a predetermined shape on a lower principal surface of the green sheet 11a, and a conductive paste 17 to form the coil conductor pattern 7 is coated in a predetermined shape on an upper principal surface of the green sheet 11d.

Then, as shown in FIG. 2C, the green sheets 11a to 11d are laminated.

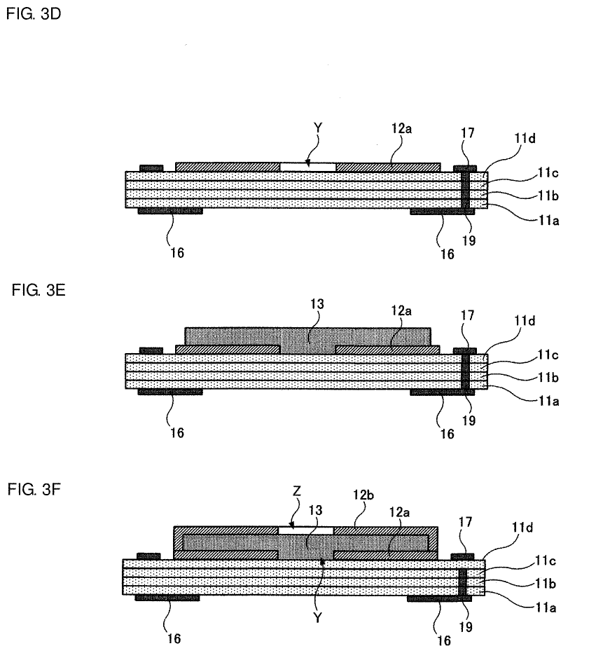

Then, as shown in FIG. 3D, a firing-vanishing sheet 12a that vanishes when subjected to firing is laminated on the upper principal surface of the green sheet 11d. The firing-vanishing sheet 12a can be made of any suitable material. For example, a mixture provided by adding a predetermined amount of carbon powder to resin may be used as the firing-vanishing sheet 12a. A circular opening Y to form the coupling portion 4b is formed in a central portion of the firing-vanishing sheet 12a.

Then, as shown in FIG. 3E, a ceramic paste 13 prepared by adding a binder and a solvent to ceramic powder of the magnetic substance used as the second ceramic base material is coated over an upper principal surface of the firing-vanishing sheet 12a, including the opening Y.

Then, as shown in FIG. 3F, a firing-vanishing sheet 12b is laminated on the coated ceramic paste 13. A circular opening Z to form the coupling portion 4a is formed in a central portion of the firing-vanishing sheet 12b. At that time, an edge portion of the firing-vanishing sheet 12b is brought into contact with the firing-vanishing sheet 12a, and the coated ceramic paste 13 is surrounded by the firing-vanishing sheets 12a and 12b.

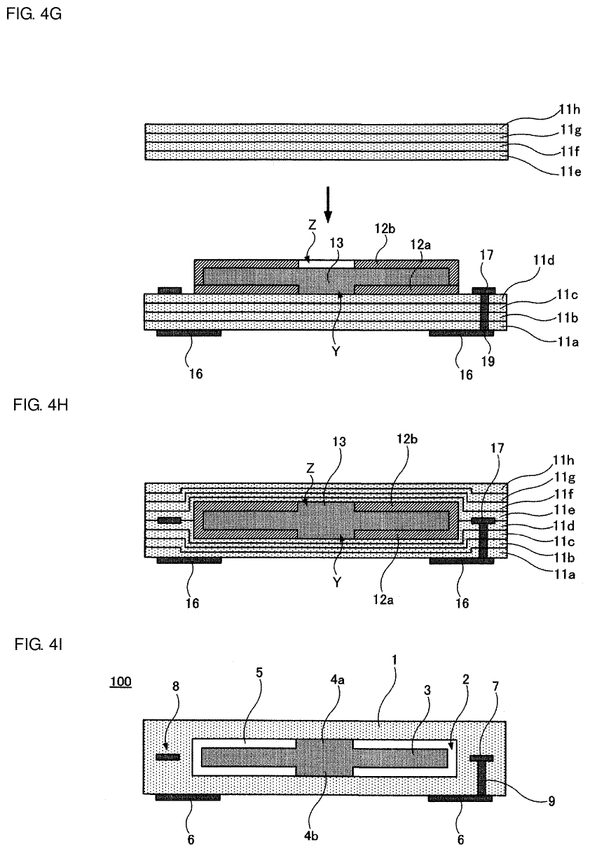

Then, as shown in FIG. 4G, the green sheets 11e to 11h are laminated on the upper principal surface of the green sheet 11d on which the firing-vanishing sheet 12a, the ceramic paste 13, and the firing-vanishing sheet 12b are formed.

Then, as shown in FIG. 4H, pressure is applied to the laminated green sheets in a vertical direction, thus pressing all of the laminated green sheets into an integral body. As a result, the green sheets 11a to 11d are pushed by the firing-vanishing sheet 12a, the ceramic paste 13, and the firing-vanishing sheet 12b to be compressed downward. Furthermore, the green sheets 11e to 11h are pushed by the firing-vanishing sheet 12a, the ceramic paste 13, and the firing-vanishing sheet 12b to be compressed upward. Moreover, in the opening Z of the firing-vanishing sheet 12b, the ceramic paste 13 is brought into contact with a lower principal surface of the green sheet 11e.

Then, all of the laminated green sheets are subjected to firing in accordance with a predetermined profile. As a result, as shown in FIG. 41, the green sheets 11a to 11h are sintered and the outer layer 1 is formed. In addition, the ceramic paste 13 is also sintered to form the intermediate layer 3 and the coupling portions 4a and 4b. On the other hand, the firing-vanishing sheets 12a and 12b vanish to form the hollow portion 2.

As described above, in the ceramic multilayer body 100, since the hollow portion 2 and further the void 5 are formed by vanishment of the firing-vanishing sheets 12a and 12b, cracks or peeling-off do not occur between the outer layer 1 and the intermediate layer 3 during the firing or the cooling after the firing.

Through the steps described above, the ceramic multilayer body 100 according to the first preferred embodiment is completed.

### Second Preferred Embodiment

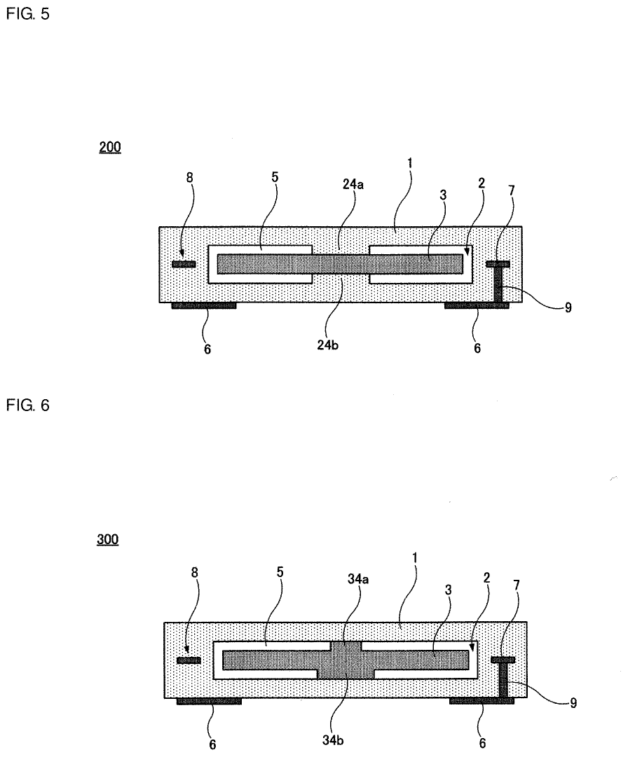

FIG. 5 shows a ceramic multilayer body 200 according to a second preferred embodiment of the present invention. FIG. 5 is a sectional view of the ceramic multilayer body 200.

The ceramic multilayer body 200 is defined by partially modifying the features of the ceramic multilayer body 100 according to the first preferred embodiment. More specifically, in the ceramic multilayer body 100, the coupling portions 4a and 4b each include the magnetic substance used as the second ceramic base material, i.e., the same or similar material as that of the intermediate layer 3. On the other hand, in the ceramic multilayer body 200, coupling portions 24a and 24b each include the nonmagnetic substance used as the first ceramic base material, i.e., the same or similar material as that of the outer layer 1. The other features of the ceramic multilayer body 200 are the same as or similar to those of the ceramic multilayer body 100.

Thus, the coupling portions 24a and 24b may each include the nonmagnetic substance used as the first ceramic base material, i.e., the same or similar material as that of the outer layer 1.

### Third Preferred Embodiment

FIG. 6 shows a ceramic multilayer body 300 according to a third preferred embodiment of the present invention. FIG. 6 is a sectional view of the ceramic multilayer body 300.

The ceramic multilayer body 300 is also defined by partially modifying the features of the ceramic multilayer body 100 according to the first preferred embodiment. More specifically, in the ceramic multilayer body 100, when observed through the ceramic multilayer body 100 in the lamination direction of the outer layer 1 and the intermediate layer 3, the size of the coupling portion 4a and the size of the coupling portion 4b are preferably the same or substantially the same. On the other hand, in the ceramic multilayer body 300, the size of a coupling portion 34a and the size of a coupling portion 34b are different from each other, and the coupling portion 34b is larger than the coupling portion 34a. The other features of the ceramic multilayer body 300 are the same as or similar to those of the ceramic multilayer body 100.

Thus, the size of the coupling portion 34a and the size of the coupling portion 34b may be different from each other.

### Fourth Preferred Embodiment

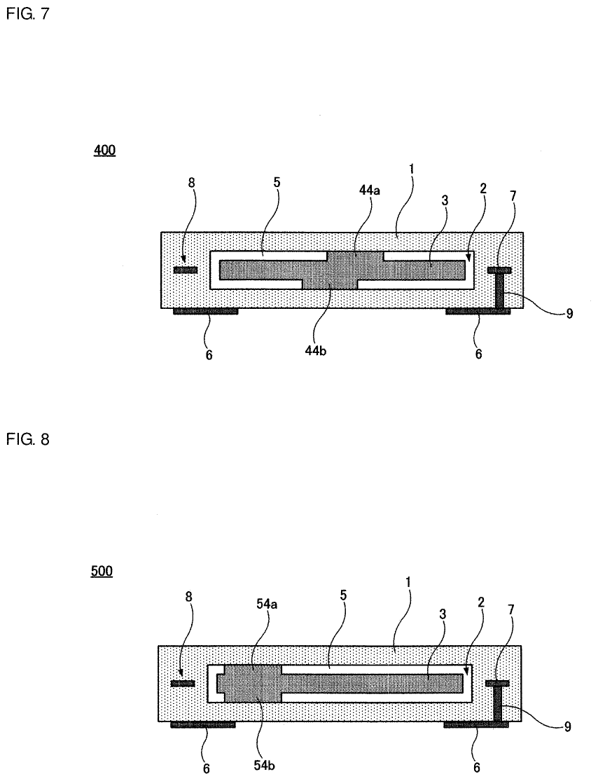

FIG. 7 shows a ceramic multilayer body 400 according to a fourth preferred embodiment of the present invention. FIG. 7 is a sectional view of the ceramic multilayer body 400.

The ceramic multilayer body 400 is also defined by partially modifying the features of the ceramic multilayer body 100 according to the first preferred embodiment. More specifically, in the ceramic multilayer body 100, when observed through the ceramic multilayer body 100 in the lamination direction, the coupling portion 4a and the coupling portion 4b are preferably provided at the same or substantially the same position. On the other hand, in the ceramic multilayer body 400, a position at which a coupling portion 44a is provided is different from a position at which a coupling portion 44b is provided. However, preferably, when observed through the ceramic multilayer body 100 in the lamination direction, the coupling portion 44a and the coupling portion 44b at least partially overlap with each other, for example. This is because, if the coupling portion 44a and the coupling portion 44b do not overlap with each other at all, a state of supporting the intermediate layer 3 inside the hollow portion 2 is very unstable. The other features of the ceramic multilayer body 400 are the same as or similar to those of the ceramic multilayer body 100.

Thus, when observed through the ceramic multilayer body in the lamination direction, the position at which the coupling portion 44a is provided may be different from the position at which the coupling portion 44b is provided.

### Fifth Preferred Embodiment

FIG. 8 shows a ceramic multilayer body 500 according to a fifth preferred embodiment of the present invention. FIG. 8 is a sectional view of the ceramic multilayer body 500.

The ceramic multilayer body 500 is also defined by partially modifying the features of the ceramic multilayer body 100 according to the first preferred embodiment. More specifically, in the ceramic multilayer body 100, when observed through the ceramic multilayer body 100 in the lamination direction, the coupling portions 4a and 4b are provided at the position overlapping with the center of gravity of the intermediate layer 3. On the other hand, in the ceramic multilayer body 500, coupling portions 54a and 54b are provided at a position offset to one side of the hollow portion 2. The other features of the ceramic multilayer body 500 are the same as or similar to those of the ceramic multilayer body 100.

Thus, when observed through the ceramic multilayer body in the lamination direction, the position at which the coupling portion 54a and 54b are formed may be offset to one side of the hollow portion 2.

### Sixth Preferred Embodiment

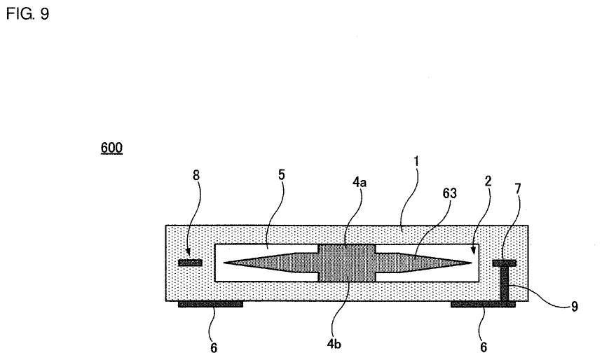

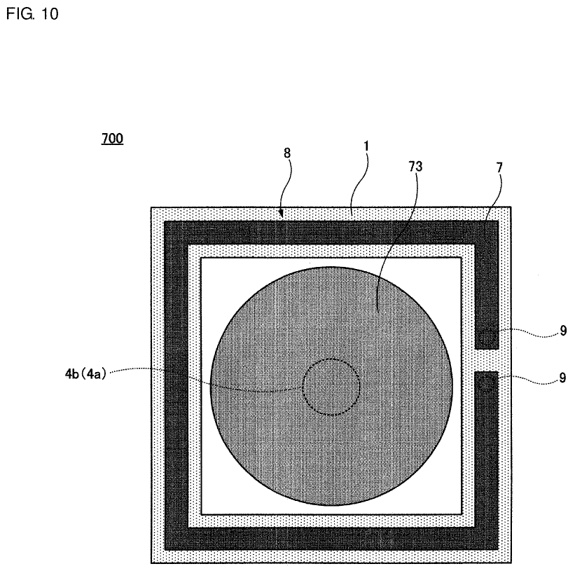

FIG. 9 shows a ceramic multilayer body 600 according to a sixth preferred embodiment of the present invention. FIG. 9 is a sectional view of the ceramic multilayer body 600.

The ceramic multilayer body 600 is also defined by partially modifying the features of the ceramic multilayer body 100 according to the first preferred embodiment. More specifically, in the ceramic multilayer body 100, the thickness of the intermediate layer 3 is uniform or substantially uniform. On the other hand, in the ceramic multilayer body 600, an intermediate layer 63 preferably has a thickness gradually decreasing toward an outer edge. The other features of the ceramic multilayer body 600 are the same as or similar to those of the ceramic multilayer body 100.

Thus, the thickness of the intermediate layer 63 is not always required to be uniform or substantially uniform.

### Seventh Preferred Embodiment

FIG. 10 shows a ceramic multilayer body 700 according to a seventh preferred embodiment of the present invention. FIG. 10 is a sectional view of the ceramic multilayer body 700.

The ceramic multilayer body 700 is also defined by partially modifying the features of the ceramic multilayer body 100 according to the first preferred embodiment. More specifically, in the ceramic multilayer body 100, when observed through the ceramic multilayer body 100 in the lamination direction, the intermediate layer 3 preferably has a rectangular or substantially rectangular shape. On the other hand, in the ceramic multilayer body 700, an intermediate layer 73 preferably has a circular or substantially circular shape. The other features of the ceramic multilayer body 700 are the same as or similar to those of the ceramic multilayer body 100.

Thus, when observed through the ceramic multilayer body in the lamination direction, the intermediate layer may have any suitable shape, for example, a circular shape as in the intermediate layer 73.

### Eighth Preferred Embodiment

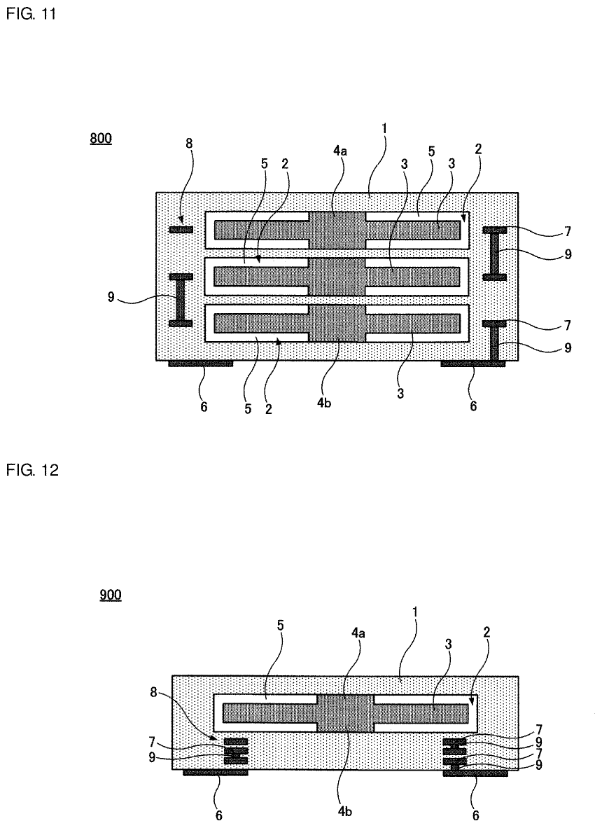

FIG. 11 shows a ceramic multilayer body 800 according to an eighth preferred embodiment of the present invention. FIG. 11 is a sectional view of the ceramic multilayer body 800.

The ceramic multilayer body 100 according to the first preferred embodiment includes one intermediate layer 3. On the other hand, in the ceramic multilayer body 800, three intermediate layers 3 are provided inside the outer layer 1.

Thus, the plurality of intermediate layers 3 may be provided inside the outer layer 1.

### Ninth Preferred Embodiment

FIG. 12 shows a ceramic multilayer body 900 according to a ninth preferred embodiment of the present invention. FIG. 12 is a sectional view of the ceramic multilayer body 900.

In the ceramic multilayer body 100 according to the first preferred embodiment, when observed through the ceramic multilayer body 100 in the lamination direction, the coil 8 is provided in the outer layer 1 outside the hollow portion 2. On the other hand, in the ceramic multilayer body 900, the coil 8 and the hollow portion 2 overlap with each other when observed through the ceramic multilayer body 900 in the lamination direction. Furthermore, the coil 8 is provided at a position different in height from the hollow portion 2 in the lamination direction. In the present preferred embodiment, the coil 8 is provided in the outer layer 1 in the lower side of the hollow portion 2.

Thus, the outer layer 1 and the intermediate layer 3 may have any suitable inner structures, including the position at which the coil 8 is provided, and those inner structures can be freely designed.

### Tenth Preferred Embodiment

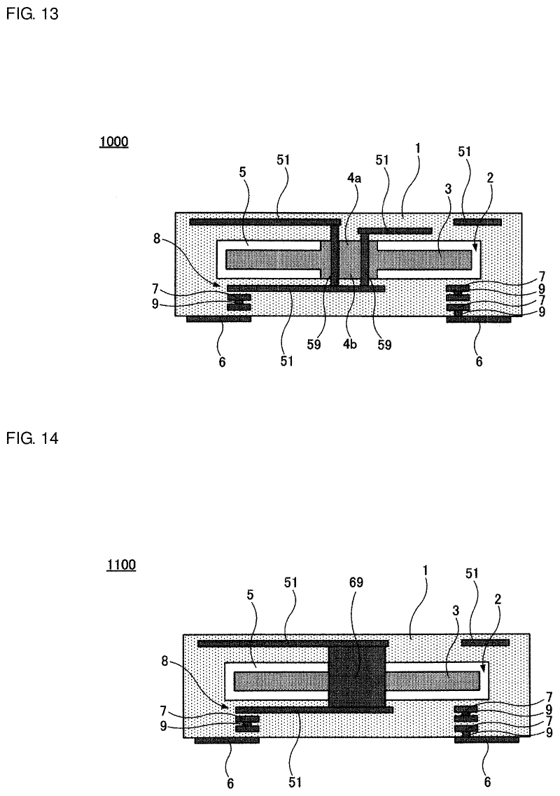

FIG. 13 shows a ceramic multilayer body 1000 according to a tenth preferred embodiment of the present invention. FIG. 13 is a sectional view of the ceramic multilayer body 1000.

The ceramic multilayer body 1000 includes a modified feature added to the features of the ceramic multilayer body 900 according to the ninth preferred embodiment. More specifically, in the ceramic multilayer body 1000, upper and lower wiring conductor patterns 51 are provided respectively above and below the hollow portion 2. Furthermore, the upper and lower wiring conductor patterns 51 are connected to each other by connection conductors (via conductors) 59 that penetrate through the intermediate layer 3 in an up-down direction.

The ceramic multilayer body 1000 defines and functions as a magnetic bead inductor (ferrite bead inductor) because the connection conductors 59 penetrate through the intermediate layer 3 that includes the magnetic substance used as the second ceramic base material. In other words, a noise component included in a signal flowing in each connection conductor 59 is significantly reduced or prevented from passing through the connection conductor 59 by the operation of the magnetic bead inductor. Moreover, since the connection conductor 59 is generally softer than the outer layer 1 and the intermediate layer 3, it further plays a role of significantly reducing the difference in thermal shrinkage rate between the outer layer 1 and the intermediate layer 3.

### Eleventh Preferred Embodiment

FIG. 14 shows a ceramic multilayer body 1100 according to an eleventh preferred embodiment of the present invention. FIG. 14 is a sectional view of the ceramic multilayer body 1100.

The ceramic multilayer body 1100 is defined by further modifying the ceramic multilayer body 1000 according to the tenth preferred embodiment. More specifically, in the ceramic multilayer body 1100, a connection conductor 69 having a larger sectional area than the connection conductor 59 in the ceramic multilayer body 1000 is provided to penetrate through the intermediate layer 3 in the up-down direction. The upper and lower wiring conductor patterns 51 are connected to each other by the connection conductor 69. Moreover, in the ceramic multilayer body 1100, the connection conductor 69 having a larger sectional area further defines and functions as a coupling portion, and the outer layer 1 and the intermediate layer 3 are coupled to each other by the connection conductor 69.

Thus, the connection conductor 69 may be provided with the operation of the coupling portion.

### Twelfth Preferred Embodiment

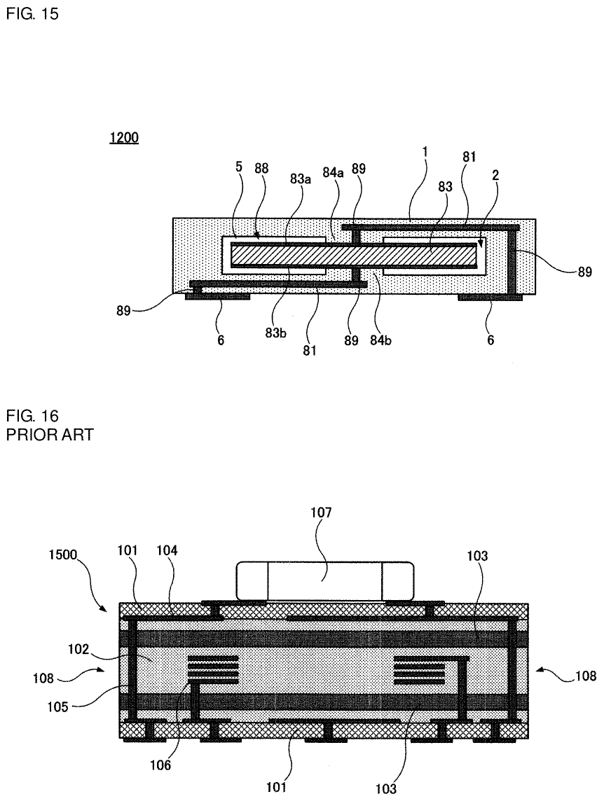

FIG. 15 shows a ceramic multilayer body 1200 according to a twelfth preferred embodiment of the present invention. FIG. 15 is a sectional view of the ceramic multilayer body 1200.

In the above-described first to eleventh preferred embodiments, the intermediate layer 3 (63 or 73) includes the magnetic substance used as the second ceramic base material. In the ceramic multilayer body 1200 according to the twelfth preferred embodiment, an intermediate layer 83 includes a piezoelectric substance instead of using the magnetic substance. Stated in another way, a piezoelectric substance is used as the second ceramic base material.

Electrodes 83a and 83b are provided on both principal surfaces of the intermediate layer 83 including the piezoelectric substance. Furthermore, the electrodes 83a and 83b are each connected to the outer electrode 6 through a wiring conductor pattern 81 and a connection conductor 89.

As a result, in the ceramic multilayer body 1200, a piezoelectric vibration component 88 is provided inside the hollow portion 2. Since the piezoelectric vibration component 88 is surrounded by the void 5 except for regions occupied by coupling portions 84a and 84b, free vibration of the piezoelectric vibration component 88 is not impeded.

In the ceramic multilayer body 1200, the coupling portions 84a and 84b include the nonmagnetic substance used as the first ceramic base material, i.e., the same or similar material as that of the outer layer 1.

Thus, the intermediate layer 83 may include the piezoelectric substance.

The first to twelfth preferred embodiments have been described above. However, the present invention is not limited to the matters described above, and the present invention can be variously modified in conformity with the gist of the present invention.

For instance, in the first to eleventh preferred embodiments, the outer layer 1 is made of the nonmagnetic substance used as the first ceramic base material, and the intermediate layer 3 (63 or 73) is made of the magnetic substance used as the second ceramic base material. In the twelfth preferred embodiment, the outer layer 1 is made of the nonmagnetic substance used as the first ceramic base material, and the intermediate layer 83 is made of the piezoelectric substance used as the second ceramic base material. However, the substance of the first ceramic base material and the substance of the second ceramic base material may be each any suitable substance, and various substances may be optionally used in suitable combinations as the first and second ceramic base materials.

While, in the first to eleventh preferred embodiments, the coil 8 is provided inside the outer layer 1, the coil 8 may be provided inside the intermediate layer 3 (63 or 73) instead of the outer layer 1. The number of turns of the coil 8 can also be set to any suitable value and is not limited to the above-mentioned number of turns.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A ceramic multilayer body that includes layers laminated in a predetermined lamination direction and including a layer of a first ceramic base material and a layer of a second ceramic base material, the first ceramic base material and the second ceramic base material having different material compositions from each other, the ceramic multilayer body comprising:
an outer layer including the first ceramic base material;
a hollow portion provided in an inner side of the outer layer and being hollow;
an intermediate layer including the second ceramic base material and provided inside the hollow portion; and
a pair of coupling portions each coupling one of two principal surfaces of the intermediate layer to the outer layer; wherein
a void is defined by the hollow portion between the outer layer and the intermediate layer except for regions occupied by the coupling portions; and
when observed through the ceramic multilayer body in the lamination direction:
the pair of coupling portions at least partially overlap with each other; and
areas of the pair of coupling portions are each smaller than an area of the intermediate layer.

2. The ceramic multilayer body according to claim 1, wherein the coupling portion includes the second ceramic base material.

3. The ceramic multilayer body according to claim 1, wherein the coupling portion includes the first ceramic base material.

4. The ceramic multilayer body according to claim 1, wherein at least a portion of the coupling portion includes metal.

5. The ceramic multilayer body according to claim 1, further comprising:
a coil conductor pattern provided inside the ceramic multilayer body; wherein
the coil conductor pattern is wound about a winding axis extending in the lamination direction; and
the coil conductor pattern defines a coil.

6. The ceramic multilayer body according to claim 1, further comprising:
wiring conductor patterns provided inside the ceramic multilayer body; wherein
the wiring conductor patterns are provided respectively in portions of the outer layer in opposite sides sandwiching the intermediate layer therebetween; and
the wiring conductor patterns are electrically connected to each other by a connection conductor provided in the intermediate layer.

7. The ceramic multilayer body according to claim 1, wherein the second ceramic base material is a magnetic substance.

8. The ceramic multilayer body according to claim 1, wherein the second ceramic base material is a piezoelectric substance.

9. The ceramic multilayer body according to claim 1, wherein, when observed through the ceramic multilayer body in the lamination direction, the coupling portion has a circular or elliptic shape.

10. The ceramic multilayer body according to claim 1, wherein, when observed through the ceramic multilayer body in the lamination direction, the coupling portion is provided at a position overlapping with a center of gravity of the intermediate layer.

11. The ceramic multilayer body according to claim 1, wherein the first ceramic base material is a nonmagnetic substance.

12. The ceramic multilayer body according to claim 11, wherein the nonmagnetic substance is alumina or nonmagnetic ferrite.

13. The ceramic multilayer body according to claim 7, wherein the magnetic substance is ferrite including iron oxide as a main component, and at least one of zin, nickel and copper.

14. The ceramic multilayer body according to claim 1, wherein, when observed through the ceramic multilayer body in the lamination direction, the coupling portion has a rectangular parallelepiped or substantially rectangular parallelepiped shape.

15. The ceramic multilayer body according to claim 5, wherein the coil conductor pattern is electrically connected to an outer electrode provided on an exterior surface of the multilayer body.

16. The ceramic multilayer body according to claim 6, wherein the connection conductor is electrically connected to an outer electrode provided on an exterior surface of the multilayer body.

17. The ceramic multilayer body according to claim 5, wherein the coil is defined by one turn of winding of the coil conductor pattern.
